(19) United States
(12) Patent Application Publication
(10) Pub. No.: US 2024/0312970 A1
(43) Pub. Date: Sep. 19, 2024

(54) DISPLAY PANELS AND METHODS FOR PREPARING THE SAME

(71) Applicant: Shenzhen China Star Optoelectronics Semiconductor Display Technology Co., Ltd., Shenzhen (CN)

(72) Inventor: Shulin CHEN, Shenzhen (CN)

(73) Assignee: Shenzhen China Star Optoelectronics Semiconductor Display Technology Co., Ltd., Shenzhen (CN)

(21) Appl. No.: 18/525,871

(22) Filed: Dec. 1, 2023

(30) Foreign Application Priority Data
Mar. 13, 2023 (CN) 202310301692.2

(51) Int. Cl. H01L 25/16; H01L 25/075; H01L 27/12; H01L 27/15; H01L 33/62

(52) U.S. Cl. CPC H01L 25/167; H01L 25/0753; H01L 27/1244; H01L 27/156; H01L 33/62; H01L 2933/0066

(57) ABSTRACT

The present disclosure provides a display panel and a method for preparing the same; the display panel includes an LED layer and a TFT device layer disposed on the LED layer, the LED layer includes a first epitaxial layer, a second epitaxial layer, and a third epitaxial layer disposed in stack; and the LED layer form a longitudinal integrated structure.

### CROSS-REFERENCE TO RELATED APPLICATION

The present disclosure claims the priority to and benefit of Chinese Patent Application No. 202310301692.2, filed on Mar. 13, 2023, the disclosure of which is incorporated herein by reference in its entirety.

### TECHNICAL FIELD

The present disclosure relates to the field of display, and in particular, to display panels and methods for preparing the same.

### BACKGROUND

The micro light-emitting diodes (Micro LEDs) array can achieve an ultra-high density of pixel level and have self luminous characteristics. Compared to organic light-emitting diodes (OLEDs) and liquid crystal displays (LCDs), the Micro LEDs have higher luminous efficiency, longer life, higher brightness, and a faster response speed, as well as advantages such as lightweight and power saving. The Micro LEDs have high application potential in various display fields such as a small-sized wear, virtual reality (VR), augmented reality (AR), a mobile phone, a tablet, a television (TV), and the like, and are an important choice for the next generation of mainstream display technology.

The Micro LED transfer and bonding technology are important thresholds for realizing mass production of the Micro LEDs. The Micro LED transfer technology is the key technology in the mass production of the Micro LEDs. For the red (R)/green (G)/blue (B) full color displays, because each process can only produce chips with one color, it is necessary to separately transfer R chips, G chips, and B chips, and accurately locate the chips, which greatly increases the difficulty of the transfer process. At present, the existing transfer and bonding technology are not compatible with yield and transfer efficiency. Therefore, how to realize high efficiency and high yield of transfer and welding of the R chips, the G chips, and B chips, to realize commercialization, remains a technical challenge that existing technologies need to overcome.

Based on the above, existing Micro LED display panels have the problem of incompatibility between the massive transfer technology and the bonding technology in yield and transfer efficiency. Therefore, it is necessary to provide a display panel to improve the problem mentioned above.

### SUMMARY

Embodiments of the present disclosure provide a display panel, including:

a substrate;

a light-emitting diode (LED) layer disposed on the substrate; in which the LED layer includes a first epitaxial layer, a second epitaxial layer, and a third epitaxial layer disposed in stack;

a thin film transistor (TFT) device layer disposed on the LED layer, in which the TFT device layer and the LED layer form a longitudinal integrated structure; and

a metal wiring layer disposed on the TFT device layer and configured to provide a driving signal for the display panel.

Embodiments of the present disclosure provide a method for preparing a display panel, including:
providing three types of epitaxial wafers with different colors of emitted light and forming at least one epitaxial layer;
bonding the at least one epitaxial layer and forming a stacked epitaxial layer;
forming a TFT device layer on the stacked epitaxial layer;
processing the stacked epitaxial layer and the TFT device layer to form a plurality of independent LED units and a plurality of independent TFT units, and etching each of the independent LED units to form a N region and a P region, and a co-N structure or a co-P structure;
forming a planarization layer on the TFT device layer, forming a via hole on the planarization layer, and forming a metal wiring layer on the planarization layer; and
forming a surface insulation layer on the metal wiring layer.

### BRIEF DESCRIPTION OF THE DRAWINGS

In order to explain technical solutions in embodiments of the present disclosure more clearly, the following will briefly introduce the drawings needed to be used in description of the embodiments. Apparently, the drawings in the following description are only some embodiments of the present disclosure. For ordinary skilled in the art, other drawings can be obtained from these drawings without paying creative effort.

FIG. 1a is a schematic diagram of a traditional Micro LED display device.

FIG. 1b is a schematic partial diagram of a traditional Micro LED display device.

FIG. 1c is a schematic cross-sectional diagram taken along a line I′-I′ in FIG. 1b.

FIG. 2a is a schematic planar diagram of a display panel provided by some embodiments of the present disclosure.

FIG. 2b is a front view diagram of a Micro LED display unit of a display panel provided by some embodiments of the present disclosure.

FIG. 3 is a schematic cross-sectional diagram taken along a line I-I in FIG. 2b.

FIG. 4 is a schematic cross-sectional diagram taken along a line II-II in FIG. 2b.

FIG. 5 is a schematic diagram of an equivalent circuit of a LED in a display panel provided by some embodiments of the present disclosure.

FIGS. 6a-6f are schematic structural diagrams in a process for preparing a display panel provided by some embodiments of the present disclosure.

FIGS. 7a-7l and FIGS. 7a′-7l′ are schematic structural diagrams in an up-down process for preparing an independent LED unit and an independent TFT unit.

### DETAILED DESCRIPTION

Each of the following embodiments is described with reference to the attached drawings to illustrate specific embodiments that can be used to be implemented in the present disclosure. Directional terms mentioned in the present disclosure, such as [on], [upper], [lower], [front], [rear], [left], [right], [inner], [outer], [side], and the like, refer only to the direction of the attached drawings. Therefore, the directional terms used are intended to illustrate and understand the present disclosure and not to limit it. In the drawings, elements with similar structures are represented by the same numeral.

The following is a further explanation of the present disclosure with reference to the attached drawings and specific embodiments.

Embodiments of the present disclosure provide a display panel, which can solve a problem of massive transfer and bonding in existing Micro LED display panels.

At present, there are technical bottlenecks in the Micro LEDs to be broken through, in which the massive transfer technology is the most critical technology. Specifically, after chips are manufactured, micron-sized crystalline grains need to be transferred to a driving circuit substrate, the number of crystalline grains in the transfer process is enormous, and display products using the Micro LEDs have lower tolerance for pixels. For example, for a full-color 1920*1080 display screen with at least five dead pixels, the yield needs to reach 99.9999%, which is difficult to achieve in existing processes.

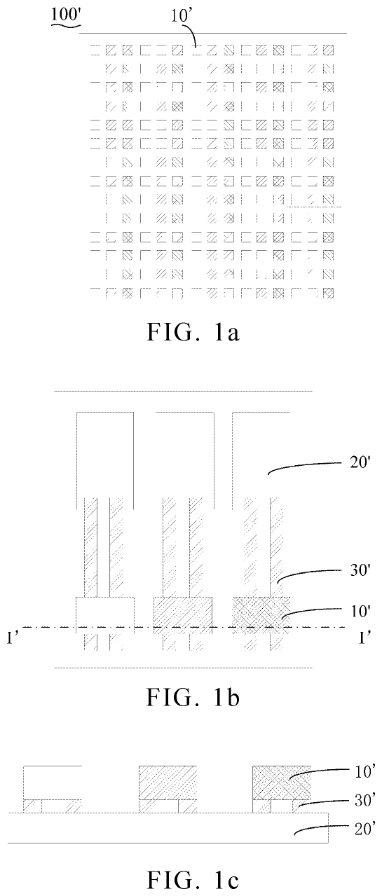

Further, as shown in FIGS. 1a-1c, FIG. 1a is a schematic diagram of a traditional Micro LED display device, FIG. 1b is a schematic partial diagram of FIG. 1a, and FIG. 1c is a schematic cross-sectional diagram taken along a line I′-I′ in FIG. 1b. As shown in FIG. 1a, a Micro LED display device 100′ includes multiple Micro LED chips 10′ arranged in an array, and each of the Micro LED chips 10′ is any one of a red chip, a green chip, and a blue chip. In a row direction, the Micro LED chips 10′ are periodically arranged with R/G/B as a minimum repeating unit; and in a column direction, each column of Micro LED chips 10′ emit the same emission color. For the R/G/B full color display, because each process can only produce one color of chips, it is necessary to separately transfer R chips, G chips, and B chips, and accurately locate the chips, which greatly increases the difficulty of the transfer process. As shown in FIG. 1b, the Micro LED chip 10′ and a TFT 20′ are horizontally integrated through a pin 30′, but the horizontal integration inevitably has problems of occupying a larger area and soldering. As shown in FIG. 1c, in a thickness direction of the Micro LED display device 100′, the Micro LED chip 10′ is disposed on the TFT 20′, and the pin 30′ is disposed between the Micro LED chip 10′ and the TFT 20′.

Based on the above, the present disclosure provides a display panel that integrates three types of R/G/B LED epitaxial layers with a TFT device layer in a longitudinal direction, and then an overall display device is prepared to solve the technical challenges of massive transfer and bonding.

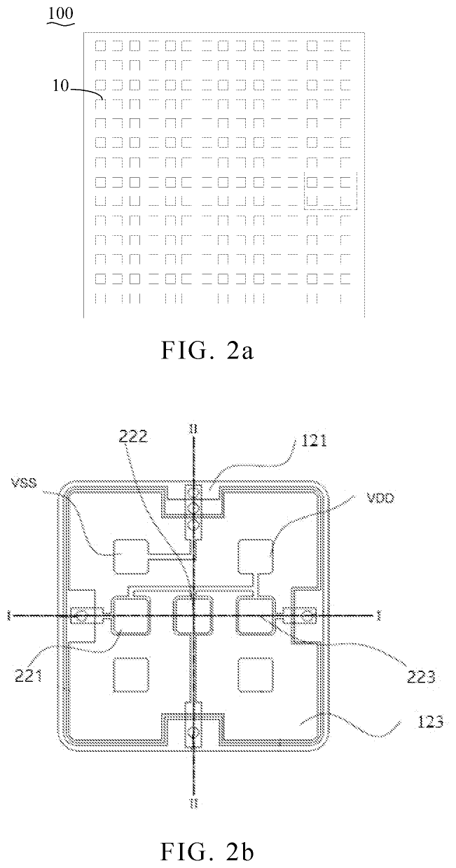

As shown in FIG. 2a, embodiments of the present disclosure provide a display panel 100 that includes multiple Micro LED display units 10 arranged in an array. Each Micro LED display unit 10 includes a first pixel, a second pixel, and a third pixel, and colors of emitted light of the first pixel, the second pixel, and the third pixel are different. In some embodiments, a color of emitted light of any one of the first pixel, the second pixel, and the third pixel is one of red, green, and blue. As shown in FIG. 2b, FIG. 2b is a front view diagram of the Micro LED display unit 10 of the display panel 100 in some embodiments of the present disclosure, the Micro LED display unit 10 includes epitaxial layers disposed in stack and a metal wiring disposed on the epitaxial layers.

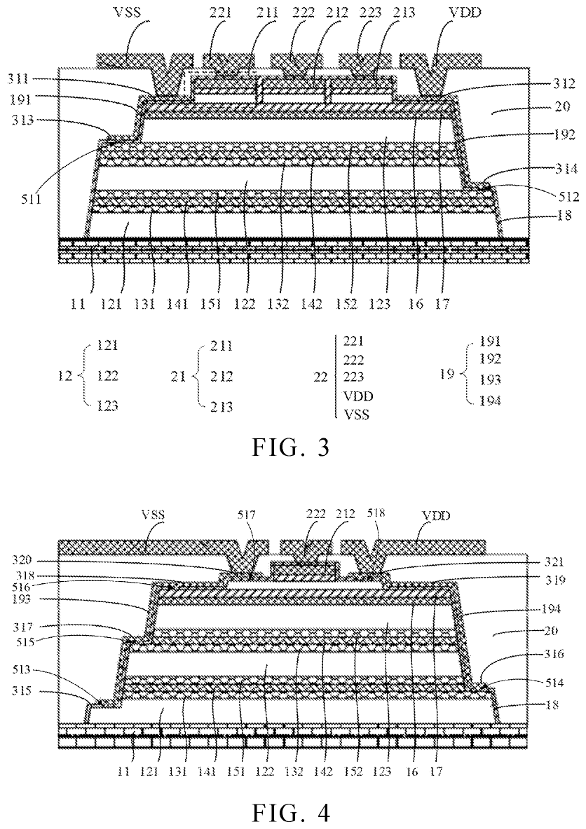

As shown in FIG. 3, FIG. 3 is a schematic cross-sectional diagram taken along a line I-I in FIG. 2b, the display panel 100 includes a substrate 11, an LED layer, and a TFT device layer 21. The substrate 11 includes, but not limited to, a sapphire substrate or a silicon substrate. The LED layer is disposed on the substrate 11; the TFT device layer 21 is disposed on the LED layer; and the LED layer and the TFT device layer 21 form a longitudinal integrated structure.

A cross-sectional area of the TFT device layer 21 is less than a cross-sectional area of the LED layer, so that edges of two sides of the TFT device layer 21 do not coincide with edges of two sides of the LED layer. Further, a first step portion 311 and a second step portion 312 are formed by the TFT device layer 21 and the LED layer.

In some embodiments, the TFT device layer 21 includes a first TFT 211, a second TFT 212, and a third TFT 213 disposed at intervals and corresponding to the first pixel, the second pixel, and the third pixel, respectively.

Compared to traditional Micro LEDs that are integrated in the horizontal direction, by integrating the LED layer with the TFT device layer 21 in the longitudinal direction, on the one hand, the present disclosure solves the problems of massive transfer and welding, on the other hand, the present disclosure greatly reduces an occupied area of each Micro LED display unit 10, allowing the display panel to integrate more Micro LED display units 10 under the same area, thereby greatly improving resolution of the display panel 100. For example, in an independent unit of the traditional Micro LED display panel 100′ that integrates Micro LEDs in the horizontal direction, since the TFT devices, wirings, storage capacitors, and Micro LEDs are disposed in the same plane, the Micro LEDs only occupy a part of the entire area of the independent unit. The proportion of the occupied area of the Micro LEDs is related to resolution and the size of the Micro LEDs, the present disclosure can reduce the two-dimensional size of the Micro LED display unit 10 to one fifth of its original size, and the smaller the size of the Micro LED display unit 10, the higher the PPI.

The LED layer includes a first epitaxial layer 121, a second epitaxial layer 122, and a third epitaxial layer 123 disposed in stack, and the above three layers form a stacked epitaxial layer 12. Further, the first epitaxial layer 121, the second epitaxial layer 122, and the third epitaxial layer 123 may have different sizes. Specifically, the first epitaxial layer 121, the second epitaxial layer 122, and the third epitaxial layer 123 may have different areas in a front view, and have different widths in a cross-sectional view. In some embodiments, the areas of the first epitaxial layer 121, the second epitaxial layer 122, and the third epitaxial layer 123 in a front view decrease sequentially in a stacking direction from the first epitaxial layer 121 to the third epitaxial layer 123. As shown in FIG. 3, the first epitaxial layer 121, the second epitaxial layer 122, and the third epitaxial layer 123 are in a stepped shape as a whole; a third step portion 313 is formed by a part of the second epitaxial layer 122 that is not covered by the third epitaxial layer 123 and the third epitaxial layer 123; and a fourth step portion 314 is formed by a part of the first epitaxial layer 121 that is not covered by the second epitaxial layer 122 and the second epitaxial layer 122.

It should be noted that each of the epitaxial layers described above can emit colored light of visible light in various bands. Further, colors of emitted light of the above three epitaxial layers are different.

In some embodiments, the color of emitted light of any one of the first epitaxial layer 121, the second epitaxial layer 122, and the third epitaxial layer 123 is one of red, green, and blue.

In some embodiments, the first pixel, the second pixel, and the third pixel correspond to the first epitaxial layer 121, the second epitaxial layer 122, and the third epitaxial layer 123, respectively.

In some embodiments, semiconductor materials in one of the above three epitaxial layers that can emit red light include, but not limited to, indium gallium nitride (InGaN), aluminum gallium arsenide (AlGaAs), gallium arsenide phosphide (GaAsP), aluminum gallium indium phosphide (AlGaInP), and gallium phosphide (GaP); and semiconductor materials in one of the above three epitaxial layers that can emit green light include, but not limited to, indium gallium nitride (InGaN), gallium nitride (GaN), gallium phosphide (GaP), aluminum gallium indium phosphide (AlGaInP), and aluminum gallium phosphide (AlGaP); and semiconductor materials that can emit blue light in one of the above three epitaxial layers include, but not limited to, gallium nitride (GaN), indium gallium nitride (InGaN), and zinc selenide (ZnSe).

Continuing to refer to FIG. 3, a first bonding layer 131 and a first filter layer 141 are sequentially disposed between the first epitaxial layer 121 and the second epitaxial layer 122, and a second bonding layer 132 and a second filter layer 142 are sequentially disposed between the second epitaxial layer 122 and the third epitaxial layer 123.

In some embodiments, materials of the above bonding layers include but not limited to metals with a low melting point, such as indium (In), stannum (Sn), and the like. The present disclosure does not specifically limit the materials of the bonding layers, as long as adjacent epitaxial layers can be stably bonded. In addition, the setting of the first filter layer 141 and the second filter layer 142 avoids light-mixing between adjacent epitaxial layers.

In some embodiments, a first transparent conductive layer 151 and a second transparent conductive layer 152 are provided between the first epitaxial layer 121 and the second epitaxial layer 122, and between the second epitaxial layer 122 and the third epitaxial layer 123, respectively. Specifically, the first transparent conductive layer 151 is disposed between the first filter layer 141 and the second epitaxial layer 122, and the second transparent conductive layer 152 is disposed between the second filter layer 142 and the third epitaxial layer 123. Materials of the first transparent conductive layer 151 and the second transparent conductive layer 152 include, but not limited to, indium tin oxide (ITO). Further, the first transparent conductive layer 151 and the second transparent conductive layer 152 may serve as an electrode of an LED.

In some embodiments, a reflective layer 16 is disposed on the third epitaxial layer 123 to enhance the light reflection of the stacked epitaxial layer 12. In some embodiments, the reflective layer 16 may be a metal with high reflectivity, such as Aluminium (Al), Cuprum (Au), or Argentum (Ag). In some embodiments, the reflective layer 16 may be a distributed bragg reflector (DRB) reflective layer formed by stacking dielectric layers.

Continuing to refer to FIG. 3, a buffer layer 17 is provided between the TFT device layer 21 and the LED layer. Specifically, the buffer layer 17 is disposed between the TFT device layer 21 and the reflective layer 16. The TFT device layer 21 may be a structure having multiple film layers, such as a gate layer, a gate insulation layer, a source/drain electrode layer, and the like. The structure of the TFT device layer 21 may refer to the structure of TFT devices in existing display panels, which is not limited here.

In some embodiments, the display panel 100 also includes a surface passivation layer 18 covering a sidewall of the TFT device layer 21 and a sidewall of the LED layer (that is, also covering a sidewall of the stacked epitaxial layer 12).

In some embodiments, an inline wiring 19 is disposed on the surface passivation layer 18 and multiple via holes are provided thereon, and the TFT device layer 21 can be connected to the LED layer by setting the inline wiring 19. In some embodiments, the surface passivation layer 18 is provided with multiple via holes, and the inline wiring 19 is connected to the TFT device layer 21 and the LED layer through the via holes. Specifically, the inline wiring 19 includes a first inline wiring 191 and a second inline wiring 192, the first inline wiring 191 covers the first step portion 311 and the third step portion 313, and the second inline 192 covers the second step portion 312 and the fourth step portion 314. Further, parts of the surface passivation layer 18 located on the third step portion 313 and the fourth step portion 314 are provided with a first via hole 511 and a second via hole 512, respectively; and the first inline wiring 191 is connected to the LED layer through the first via hole 511, and the second inline wiring 192 is connected to the LED layer through the second via hole 512.

It should be noted that, by setting the surface passivation layer 18, on the one hand, a short circuit caused by the contact of the TFT device layer 21, the LED layer, and other substances in the environment, such as water and oxygen, can be avoided; on the other hand, short circuits between the TFT device layer 21 and the wirings thereon, and between the LED layer and the inline wiring 19 can be avoided. Moreover, a part of the surface passivation layer 18 covering the side wall of the LED layer can avoid a short circuit between the LED layer and the TFT device layer 21.

In some embodiments, the display panel 100 also includes a planarization layer 20 and a metal wiring layer 22, the planarization layer 20 is disposed on the TFT device layer 21 and completely covers the surface passivation layer 18 and the inline wiring 19 located on the TFT device layer 21 and the LED layer.

The metal wiring layer 22 is disposed on the planarization layer 20 and configured to provide a driving signal for the display panel 100. In some embodiments, the planarization layer 20 is provided with multiple via holes, enabling the metal wiring layer 22 to be electrically connected to the TFT device layer 21 and the LED layer through the via holes. Specifically, the metal wiring layer 22 includes a first data line 221, a second data line 222, a third data line 223, a first power line VDD, and a second power line VSS arranged at intervals. The first power line VDD is disposed corresponding to the second step portion 312, and the second power line VSS is disposed corresponding to the first step portion 311. The first data line 221, the second data line 222, and the third data line 223 are disposed corresponding to the first TFT 211, the second TFT 212, and the third TFT 213, respectively, that is, the first data line 221, the second data line 222, and the third data line 223 correspond to the first pixel, the second pixel, and the third pixel, respectively.

As shown in FIG. 4, FIG. 4 is a schematic cross-sectional diagram taken along a line II-II in FIG. 2b, in the embodiments as illustrated in FIG. 4, edges of two sides of the second epitaxial layer 122 are located within the edges of two sides of the first epitaxial layer 121, respectively, enabling the second epitaxial layer 122 and the first epitaxial layer 121 to form a fifth step portion 315 and a sixth step portion 316. A seventh step portion 317 is formed by a part of the second epitaxial layer 122 that is not covered by the third epitaxial layer 123 and the third epitaxial layer 123. Edges of two sides of the TFT device layer 21 are located within edges of two sides of the third epitaxial layer 123, respectively, enabling the TFT device layer 21 and the third epitaxial layer 123 to form an eighth step portion 318 and a ninth step portion 319. In addition, in the embodiments as illustrated in FIG. 4, the TFT device layer 21 includes the second TFT 212 that is designed in a convex shape, so that a tenth step 320 and an eleventh step 321 are formed by a part of the second TFT 212 with a smaller thickness and a part of the second TFT 212 with a larger thickness.

In some embodiments, the inline wiring 19 also includes a third inline wiring 193 and a fourth inline wiring 194, the third inline wiring 193 covers the fifth step portion 315, the seventh step portion 317, the eighth step portion 318, and the tenth step portion 320, and the fourth inline wiring 194 covers the sixth step portion 316, the ninth step portion 319, and the eleventh step portion 321. Further, parts of the surface passivation layer 18 located on the fifth step portion 315, the sixth step portion 316, the seventh step portion 317, the eighth step portion 318, the tenth step portion 320, and the eleventh step portion 321 are provided with a third via hole 513, a fourth via hole 514, a fifth via hole 515, a sixth via hole 516, a seventh via hole 517, and an eighth via hole 518, respectively. The third inline wiring 193 is connected to the TFT device layer 21 and the LED layer through the third via hole 513, the fifth via hole 515, the sixth via hole 516, and the seventh via hole 517, and the fourth inline wiring 194 is connected to the TFT device layer 21 and the LED layer through the fourth via hole 514 and the eighth via hole 518.

Further, the second data line 222 is disposed corresponding to a convex part of the second TFT 212 that is designed in the convex shape, and the first power line VDD and the second power line VSS are disposed corresponding to the eleventh step portion 321 and the tenth step portion 320 of the second TFT 212, respectively.

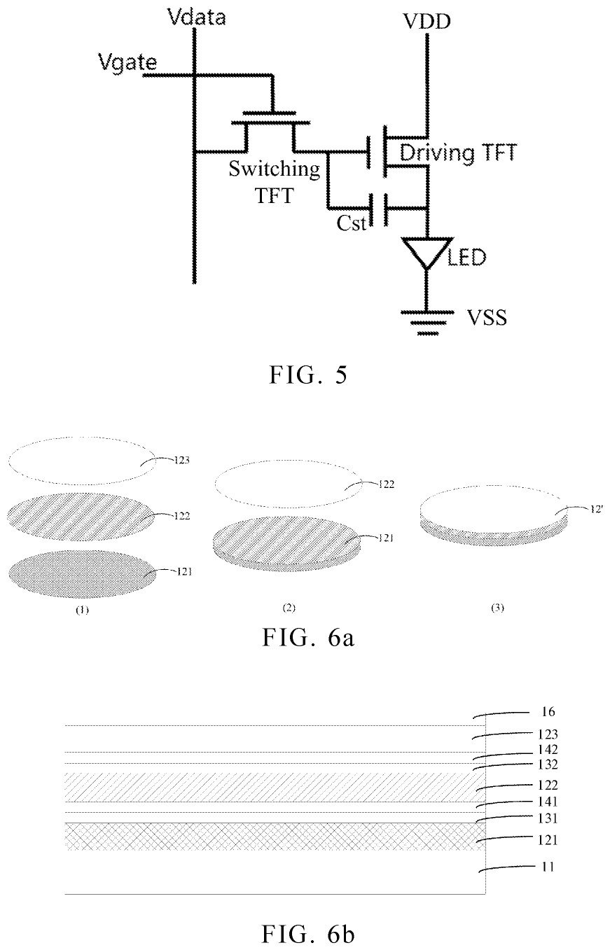

As shown in FIG. 5, FIG. 5 is a schematic diagram of an equivalent circuit of a LED in the display panel 100, the equivalent circuit can be used to drive any one of the first pixel, the second pixel, and the third pixel. The equivalent circuit may include a driving TFT, a switching TFT, and a capacitor Cst configured to switch or drive the LED.

In some embodiments, the driving TFT and the switching TFT may use any of a positive-channel-metal-oxide-semiconductor (PMOS) type transistor and a negative-channel-metal-oxide-semiconductor (NMOS) type transistor, the present disclosure does not specifically limit on this. A gate of the switching TFT is connected to a scan driver (not shown in the figures), a source of the switching TFT is connected to a data driver (not shown in the figures), and a drain of the switching TFT is connected to one end of the capacitor Cst and a gate of the driving TFT. The other end of the capacitor Cst is connected to an anode of the LED. In addition, a source of the driving TFT is connected to the first power line VDD, and a drain of the driving TFT is connected to the anode of the LED. A cathode of the LED is connected to the second power line VSS. A voltage of the second power line VSS may be less than a voltage of the first power line VDD. In some embodiments of the present disclosure, an end of the second power line VSS is grounded.

In some embodiments, an operation process of the equivalent circuit of the LED is as follows: firstly, when a gate voltage Vgate received by the scan driver is turned on by the switching TFT, a data voltage Vdata output from the data driver is transmitted to one end of the capacitor Cst and the gate of the driving TFT.

Voltages of the gate and the source corresponding to the driving TFT can be maintained for a predetermined time through the capacitor Cst. Driving current corresponding to the voltages of the gate and the source of the driving TFT can be applied to the anode of the LED, enabling the LED to emit light.

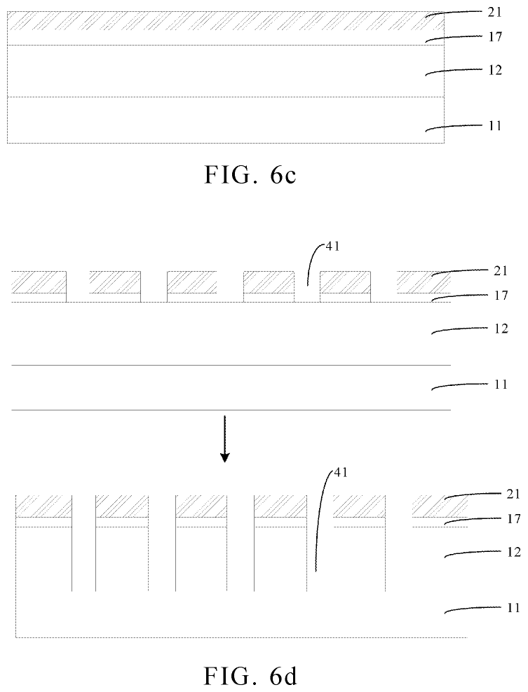

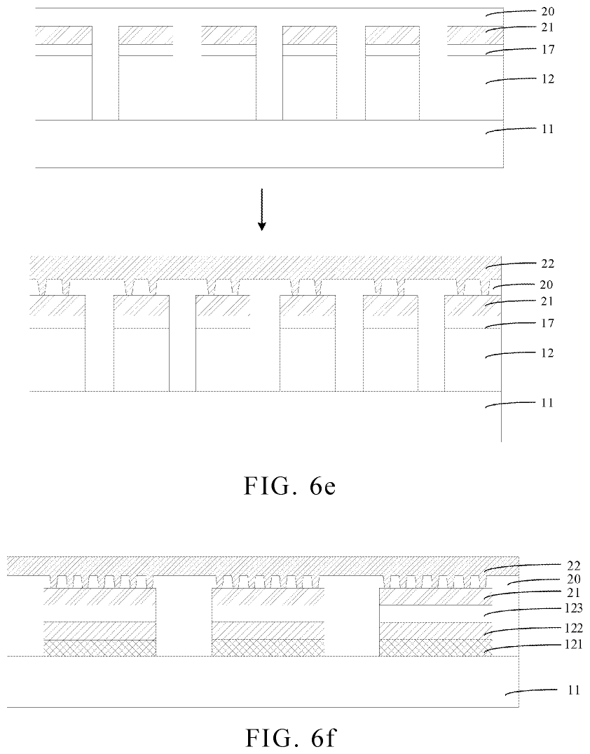

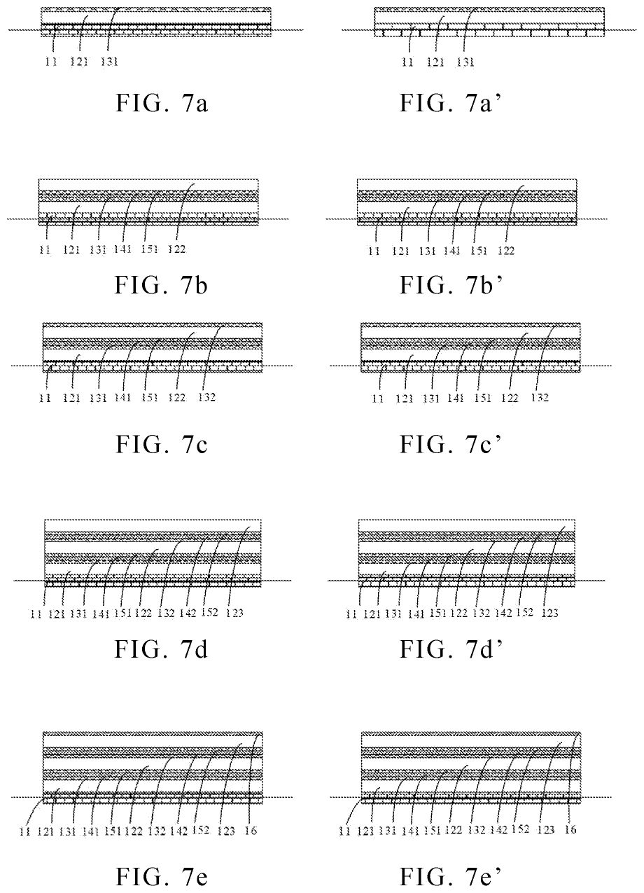

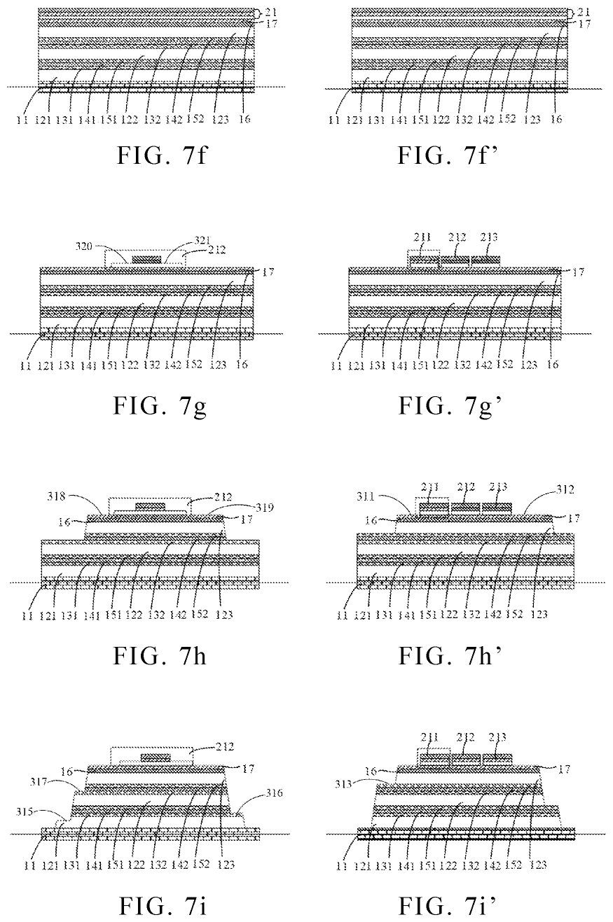

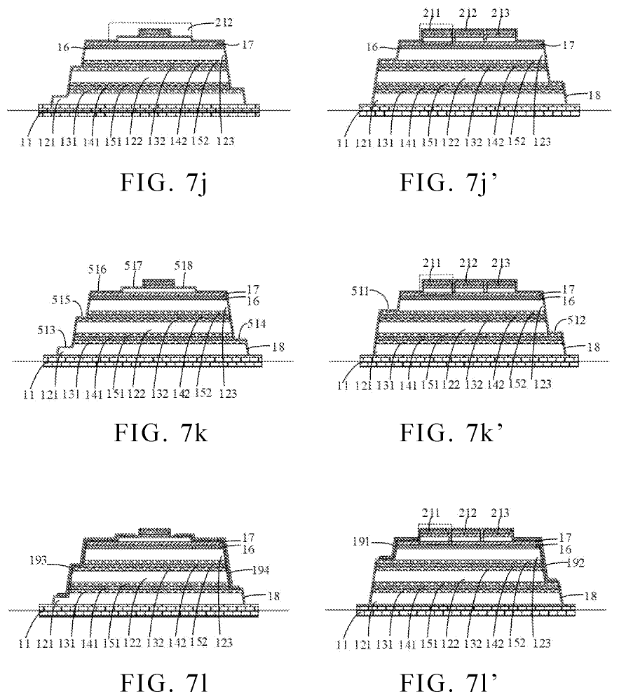

Referring to FIG. 3, FIG. 4, FIGS. 6a-6f, FIGS. 7a-7l, and FIGS. 7a′-7l′, embodiments of the present disclosure provide a method for preparing the above-mentioned display panel 100, including the following steps S101 to S106.

At step S101, forming at least one epitaxial layer, as shown in FIG. 6a.

Three types of epitaxial wafers with different colors of emitted light are provided to form at least one epitaxial layer. Specifically, three types of epitaxial wafers with different colors of emitted light grow individually to form the first epitaxial layer 121, the second epitaxial layer 122, and the third epitaxial layer 123, respectively, as illustrated in a structure (1) of FIG. 6a; alternatively, the combination of any two epitaxial wafers among the three types of epitaxial wafers grows to form the first epitaxial layer 121, and the other epitaxial wafer among the three types of epitaxial wafers grows individually to form the second epitaxial layer 122, as illustrated in a structure (2) of FIG. 6a; alternatively, the three types of epitaxial wafers grow together to form an epitaxial layer 12′, as illustrated in a structure (3) of FIG. 6a.

It should be noted that the above-mentioned epitaxial growth process includes, but not limited to, metal-organic chemical vapor deposition (MOCVD).

At step S102, bonding of the epitaxial layers, as shown in FIG. 6b.

Taking the structure shown in the structure (1) of FIG. 6a as an example, at least two different epitaxial layers in step S101 are bonded to form the stacked epitaxial layer 12. For example, the first epitaxial layer 121, the second epitaxial layer 122, and the third epitaxial layer 123 with three different colors of emitted light are bonded. Specifically, the substrate 11 is provided, the first epitaxial layer 121 is disposed on a surface of the substrate 11, the second epitaxial layer 122 and the first epitaxial layer 121 are bonded through the first bonding layer 131, and the second epitaxial layer 122 and the third epitaxial layer 123 are bonded through the second bonding layer 132. Further, the first filter layer 141 is disposed between the first bonding layer 131 and the second epitaxial layer 122, and the second filter layer 142 is disposed between the second bonding layer 132 and the third epitaxial layer 123.

Alternatively, taking the structure shown in the structure (2) of FIG. 6a as an example, the first epitaxial layer 121 with two different colors of emitted light and the second epitaxial layer 122 with a different color of emitted light from the first epitaxial layer 121 may be bonded through a bonding layer, and a filter layer is provided between the bonding layer and the second epitaxial layer 122.

Further, after bonding of the epitaxial layers, the reflective layer 16 needs to be formed on the stacked epitaxial layer 12 to enhance the light reflection of the stacked epitaxial layer 12.

At step S103, the TFT device layer 21 is formed on the stacked epitaxial layer 12, as shown in FIG. 6c.

The buffer layer 17 is formed on the stacked epitaxial layer 12, and then the TFT device layer 21 is integrated on the buffer layer 17.

At step S104, the stacked epitaxial layer 12 and the TFT device layer 21 are processed to form multiple independent LED units and multiple independent TFT units, and each independent LED unit is etched to form a N region and a P region, and form a co-N structure or a co-P structure, as shown in FIG. 6d.

It should be noted that the above processing method involves simultaneous photolithography and etching. Firstly, the longitudinal photolithography and etching are performed on the TFT device layer 21 and the buffer layer 17 below thereof to form multiple grooves 41, which partition the TFT device layer 21 into multiple independent TFT units arranged regularly and at intervals. Secondly, at the position where the grooves 41 are located, the longitudinal lithography and etching are continued towards the stacked epitaxial layer 12 to the bottom of the stacked epitaxial layer 12, so that the bottom of the grooves 41 is in contact with the substrate 11. The grooves 41 partition the stacked epitaxial layer 12 into multiple independent LED units. The independent LED units individually correspond to the independent TFT units. It should be noted that the LED units emit light from the bottom, thereby avoiding loss of output light of the LED units caused by shielding of the TFT units above the LED units. In addition, during the process for processing the stacked epitaxial layers 12 to form the independent LED units, it is necessary to etch the N region and the P region of each of the independent LED units to form the co-N structure or the co-P structure and then connect N regions or P regions of all the LED units together, and the other end of each of the LED units is independently connected to the corresponding TFT unit for controlling driving current.

It should be noted that in the process for preparing the independent LED units and TFT units, an up-down process may be used. The specific process flow includes the following steps S201 to S212.

At step S201, the substrate 11 is provided and sequentially form the first epitaxial layer 121 and the first bonding layer 131 on the substrate 11, as shown in FIG. 7a and FIG. 7a′.

At step S202, the first filter layer 141 and the first transparent conductive layer 151 are sequentially formed on the first bonding layer 131, and the second epitaxial layer 122 is formed on the first transparent conductive layer 151, as shown in FIG. 7b and FIG. 7b′.

At step S203, the second bonding layer 132 is formed on the second epitaxial layer 122, as shown in FIG. 7c and FIG. 7c′.

At step S204, the second filter layer 142 and the second transparent conductive layer 152 are sequentially formed on the first bonding layer 131, and the third epitaxial layer 123 is formed on the second transparent conductive layer 152, as shown in FIG. 7d and FIG. 7d′.

At step S205, the reflective layer 16 is formed on the third epitaxial layer 123, as shown in FIG. 7e and FIG. 7e′.

At step S206, the buffer layer 17 and the TFT device layer 21 are sequentially formed on the reflective layer 16, as shown in FIG. 7f and FIG. 7f′.

At step S207, the TFT device layer 21 is etched to form the first TFT 211, the second TFT 212, and the third TFT 213.

Referring to FIG. 4 and FIG. 7g, the second TFT 212 is a convex-shaped structure, making the second TFT 212 have the tenth step portion 320 and the eleventh step portion 321. Referring to FIG. 3 and FIG. 7g′, the first TFT 211, the second TFT 212, and the third TFT 213 are disposed at intervals.

At step S208, the third epitaxial layer 123 is etched.

Specifically, etching sequentially downwards in a direction facing the substrate 11. Referring to FIG. 4 and FIG. 7h, the buffer layer 17, the reflective layer 16, the third epitaxial layer 123, the second transparent conductive layer 152, and the second filter layer 142 are sequentially etched downwards, so that the second TFT 212 and the third epitaxial layer 123 form the eighth step portion 318 and the ninth step portion 319. Referring to FIG. 3 and FIG. 7h′, the buffer layer 17, the reflective layer 16, and the third epitaxial layer 123 are sequentially etched downwards, so that the TFT device layer 21 including the first TFT 211, the second TFT 212, and the third TFT 213 and the third epitaxial layer 123 form the first step portion 311 and the second step portion 312.

At step S209, the second epitaxial layer 122 and the first epitaxial layer 121 are etched.

Referring to FIG. 4 and FIG. 7i, the second bonding layer 132, the second epitaxial layer 122, the first transparent conductive layer 151, and the first filter layer 141 are sequentially etched downwards, so that the second epitaxial layer 122 and the third epitaxial layer 123 form the seventh step portion 317, and the first epitaxial layer 121 and the second epitaxial layer 122 form the sixth step portion 316 at a side opposite to the seventh step portion 317. Referring to FIG. 3 and FIG. 7i′, the second transparent conductive layer 152, the second filter layer 142, the second bonding layer 132, and the second epitaxial layer 122 are sequentially etched downwards, so that the second epitaxial layer 122 and the third epitaxial layer 123 form the third step portion 313.

Continue to refer to FIG. 4 and FIG. 7i, etching sequentially downwards continuously, the first bonding layer 131 and the first epitaxial layer 121 are sequentially etched downwards at a side close to the seventh step portion 317, so that the first epitaxial layer 121 and the second epitaxial layer 122 form the fifth step portion 315. Continue to refer to FIG. 3 and FIG. 7i′, the first epitaxial layer 121 and the second epitaxial layer 122 also form the fourth step portion 314.

At step S210, the surface passivation layer 18 is formed on the TFT device layer 21 and the LED layer, as shown in FIG. 7j and FIG. 7j′.

It should be noted that the surface passivation layer 18 completely covers the sidewalls of the TFT device layer 21 and the LED layer.

At step S211, via holes are formed in the surface passivation layer 18.

Referring to FIG. 4 and FIG. 7k, the third via hole 513, the fourth via hole 514, the fifth via hole 515, the sixth via hole 516, the seventh via hole 517, and the eighth via hole 518 are formed in parts of the surface passivation layer 18 that are located on the fifth step portion 315, the sixth step portion 316, the seventh step portion 317, the eighth step portion 318, the tenth step portion 320, and the eleventh step portion 321, respectively.

Referring to FIG. 3 and FIG. 7k′, the first via hole 511 and the second via hole 512 are formed in parts of the surface passivation layer 18 that are located on the third step portion 313 and the fourth step portion 314, respectively.

At step S212, the inline wiring 19 is formed on the surface passivation layer 18.

Referring to FIG. 4 and FIG. 7l, the third inline wiring 193 and the fourth inline wiring 194 are formed on sidewalls of two sides of the LED layer and the TFT device layer 21, respectively. Specifically, the third inline wiring 193 is formed on the surface passivation layer 18 located on the fifth step portion 315, the seventh step portion 317, the eighth step portion 318, and the tenth step portion 320; and the fourth inline wiring 194 is formed on the surface passivation layer 18 located on the sixth step portion 316, the ninth step portion 319, and the eleventh step portion 321. Further, the third inline wiring 193 is connected to the TFT device layer 21 and the LED layer through the third via hole 513, the fifth via hole 515, the sixth via hole 516, and the seventh via hole 517; and the fourth inline wiring 194 is connected to the TFT device layer 21 and the LED layer through the fourth via hole 514 and the eighth via hole 518.

Referring to FIG. 3 and in FIG. 7l′, the first inline wiring 191 and the second inline wiring 192 are formed on sidewalls of two sides of the LED layer, respectively. Specifically, the first inline wiring 191 is formed on the surface passivation layer 18 located on the first step portion 311 and the third step portion 313; and the second inline wiring 192 is formed on the surface passivation layer 18 located on the second step portion 312 and the fourth step portion 314. Further, the first inline wiring 191 is connected to the LED layer through the first via hole 511; and the second inline wiring 192 is connected to the LED layer through the second via hole 512.

In other embodiments, the independent LED units and TFT units may also be prepared through a down-up process. Different from the up-down process, after forming the substrate 11 by the down-up process, the growth of the LED layer is defined by patterning, that is, the area of the pattern of the LED layer in which the LED layer can grow epitaxially is defined on the substrate 11, and the remaining areas cannot grow epitaxially, thus, LED devices can be formed by the down-up process without etching by the photolithography process. Subsequently, the TFT device layer 21 is formed on the LED layer.

At step S105, the planarization layer 20 is formed on the TFT device layer 21, via holes are formed on the planarization layer 20, and the metal wiring layer 22 is formed, as shown in FIG. 6e.

Further, the grooves 41 that are gaps between adjacent and independent LED units and TFT units are filled with the planarization layer 20. In addition, the metal wiring layer 22 includes the first power line VDD, the second power line VSS, the first data line 221, the second data line 222, and the third data line 223. It should be noted that the method for forming the metal wiring layer 22 includes, but not limited to, evaporation. By designing the metal wiring layer 22, all independent LED units and TFT units can be individually connected, thereby realizing active control of the above-mentioned independent units.

In some embodiments, mental lines in the metal wiring layer 22 is formed by two manufacturing processes. That is, a first planarization layer is first formed, and then a first metal wiring layer is formed on the first planarization layer; subsequently, a second planarization layer is formed on the first metal wiring layer, and then a second metal wiring layer is formed on the second planarization layer, to realize arrangement of lines in a horizontal direction and a vertical direction.

At step S106, a surface insulation layer is formed on the metal wiring layer 22 and then the above prepared structure is cut to obtain the structure shown in FIG. 6f.

It should be noted that by cutting edges of the remaining epitaxial wafer, display of different sizes of areas can be realized. This display may be a single independent unit display or a regional display. The single independent unit display can be realized by cutting each independent unit and then printing a piece on a passive driven substrate to obtain the display effect.

In addition, the formation of the surface insulation layer can effectively avoid the failure of the metal wiring layer 22. The cutting method includes, but not limited to, laser irradiation.

Beneficial effects of the embodiments of the present disclosure: the embodiments of the present disclosure provide the display panel and the method for preparing the same; the display panel includes the LED layer and the TFT device layer disposed on the LED layer; the LED layer includes the first epitaxial layer, the second epitaxial layer, and the third epitaxial layer disposed in stack and forming the stacked epitaxial layer. By integrating the LED layer formed by the stacked epitaxial layer with the TFT device layer to form the longitudinal integrated structure, on the one hand, the stacked device can achieve full color display, and on the other hand, compared to the horizontal integration of LEDs and TFT devices, the longitudinal integration of LEDs and the TFT devices can greatly reduce the occupied area of each Micro LED display unit while solving the problems of massive transfer and welding, allowing the display panel to integrate more Micro LED display units under the same area, and greatly improving the resolution of the display panel.

Based on the above, although the present disclosure is disclosed as described above with preferred embodiments, the above preferred embodiments are not used to limit the present disclosure, and those skilled in the art can make various changes and embellishments without departing from the spirit and the scope of the present disclosure, which does not fall outside the scope of protection of the present disclosure as defined in the claims.

What is claimed is:

1. A display panel comprising:
a substrate;
a lighting-emitting diode (LED) layer disposed on the substrate and comprising a first epitaxial layer, a second epitaxial layer, and a third epitaxial layer disposed in stack;
a thin film transistor (TFT) device layer disposed on the LED layer, wherein the TFT device layer and the LED layer form a longitudinal integrated structure; and
a metal wiring layer disposed on the TFT device layer and configured to provide a driving signal for the display panel.

2. The display panel of claim 1, wherein a first bonding layer, a first filter layer, and a first transparent conductive layer are sequentially disposed between the first epitaxial layer and the second epitaxial layer; and a second bonding layer, a second filter layer, and a second transparent metal layer are sequentially disposed between the second epitaxial layer and the third epitaxial layer.

3. The display panel of claim 1, wherein a reflective layer is disposed on the third epitaxial layer.

4. The display panel of claim 1, further comprising:
a surface passivation layer covering a side wall of the TFT device layer and a side wall of the LED layer; and
an inline wiring disposed on the surface passivation layer;
wherein the surface passivation layer is provided with a via hole, and the inline wiring is connected to the TFT device layer and the LED layer through the via hole.

5. The display panel of claim 1, comprising a plurality of micro light-emitting diode (Micro LED) display units arranged in an array, wherein each of the plurality of Micro LED display units comprises a first pixel, a second pixel, and a third pixel; wherein the TFT device layer comprises a first TFT, a second TFT, and a third TFT disposed corresponding to the first pixel, the second pixel, and the third pixel, respectively.

6. The display panel of claim 4, further comprising:
a planarization layer disposed on the TFT device layer and covering the surface passivation layer and the inline wiring located on the TFT device layer and the LED layer; and
the metal wiring layer disposed on the planarization layer;
wherein the TFT device layer comprises a first TFT, a second TFT, and a third TFT, and the metal wiring layer comprises a first data line, a second data line, and a third data line arranged at intervals, and disposed corresponding to the first TFT, the second TFT, and the third TFT, respectively.

7. The display panel of claim 1, wherein colors of emitted light of the first epitaxial layer, the second epitaxial layer, and the third epitaxial layer are different.

8. The display panel of claim 1, wherein a first step portion and a second step portion are formed by the TFT device layer and the LED layer.

9. The display panel of claim 8, wherein the metal wiring layer comprises a first power line and a second power line arranged at intervals, wherein the first power line is disposed corresponding to the second step portion, and the second power line is disposed corresponding to the first step portion.

10. The display panel of claim 8, wherein the first epitaxial layer, the second epitaxial layer, and the third epitaxial layer are in a stepped shape as a whole, a third step portion is formed by a part of the second epitaxial layer not covered by the third epitaxial layer and the third epitaxial layer, and a fourth step portion is formed by a part of the first epitaxial layer not covered by the second epitaxial layer and the second epitaxial layer.

11. The display panel of claim 10, further comprising a surface passivation layer and an inline wiring disposed on the surface passivation layer;
wherein the surface passivation layer covers a side wall of the TFT device layer and a side wall of the LED layer; and
wherein the inline wiring comprises a first inline wiring and a second inline wiring, parts of the surface passivation layer located on the third step portion and the fourth step portion are provided with a first via hole and a second via hole, respectively; and the first inline wiring is connected to the LED layer through the first via hole, and the second inline wiring is connected to the LED layer through the second via hole.

12. The display panel of claim 10, wherein edges of two sides of the second epitaxial layer are located within edges of two sides of the first epitaxial layer, respectively, and a fifth step portion and a sixth step portion are formed by the second epitaxial layer and the first epitaxial layer.

13. The display panel of claim 12, further comprising a surface passivation layer and an inline wiring disposed on the surface passivation layer;
wherein the surface passivation layer covers a side wall of the TFT device layer and a side wall of the LED layer; and
wherein the inline wiring comprises a third inline wiring and a fourth inline wiring, parts of the surface passivation layer located on the fifth step portion and the sixth step portion are provided with a third via hole and a fourth via hole, respectively; and the third inline wiring is connected to the LED layer through the third via hole, and the fourth inline wiring is connected to the LED layer through the fourth via hole.

14. The display panel of claim 12, wherein a seventh step portion is formed by a part of the second epitaxial layer not covered by the third epitaxial layer and the third epitaxial layer;
edges of two sides of the TFT device layer are located within edges of two sides of the third epitaxial layer, respectively, and an eighth step portion and a ninth step portion are formed by the TFT device layer and the third epitaxial layer; and
the TFT device layer comprises a TFT in a convex shape, and a tenth step portion and an eleventh step portion are formed by a part of the TFT with a smaller thickness and a part of the TFT with a larger thickness in a cross-sectional view.

15. The display panel of claim 14, further comprising a surface passivation layer and an inline wiring located on the surface passivation layer;
wherein the surface passivation layer covers a side wall of the TFT device layer and a side wall of the LED layer; and
wherein the inline wiring comprises a third inline wiring and a fourth inline wiring, parts of the surface passivation layer located on the seventh step portion, the eighth step portion, the tenth step portion, and the eleventh step portion are provided with a fifth via hole, a sixth via hole, a seventh via hole, and an eighth via hole, respectively; and the third inline wiring is connected to the TFT device layer and the LED layer through the fifth via hole, the sixth via hole, and the seventh via hole, and the fourth inline wiring is connected to the TFT device layer and the LED layer through the eighth via hole.

16. The display panel of claim 1, further comprising:
a reflective layer disposed between the third epitaxial layer and the TFT device layer;
a buffer layer disposed between the reflective layer and the TFT device layer;
a surface passivation layer covering a side wall of the TFT device layer and a side wall of the LED layer;
an inline wiring disposed on the surface passivation layer; and
a planarization layer disposed on the TFT device layer and covering the surface passivation layer and the inline wiring on the TFT device layer and the LED layer, wherein the metal wiring layer is disposed on the planarization layer.

17. The display panel of claim 16, wherein a first bonding layer, a first filter layer, and a first transparent conductive layer are sequentially disposed between the first epitaxial layer and the second epitaxial layer; and a second bonding layer, a second filter layer, and a second transparent metal layer are sequentially disposed between the second epitaxial layer and the third epitaxial layer.

18. The display panel of claim 1, wherein a width of the first epitaxial layer, a width of the second epitaxial layer, and a width of the third epitaxial layer in a cross-sectional view are different.

19. A method for preparing a display panel, comprising:
providing three types of epitaxial wafers with different colors of emitted light and forming at least one epitaxial layer;
bonding the at least one epitaxial layer and forming a stacked epitaxial layer;
forming a thin film transistor (TFT) device layer on the stacked epitaxial layer;
processing the stacked epitaxial layer and the TFT device layer to form a plurality of independent lighting-emitting diode (LED) units and a plurality of independent TFT units, and etching each of the independent LED units to form a N region and a P region, and a co-N structure or a co-P structure;
forming a planarization layer on the TFT device layer, forming a via hole on the planarization layer, and forming a metal wiring layer on the planarization layer; and
forming a surface insulation layer on the metal wiring layer.

20. The method for preparing the display panel of claim 19, wherein the step of forming at least one epitaxial layer comprises:
enabling the three types of epitaxial wafers to grow individually, to form a first epitaxial layer, a second epitaxial layer, and a third epitaxial layer, respectively; or, enabling any two epitaxial wafers among the three types of epitaxial wafers to grow together to form a first epitaxial layer, and enabling another epitaxial wafer among the three types of epitaxial wafers to grow individually to form a second epitaxial layer; or, enabling the three types of epitaxial wafers to grow together to form an epitaxial layer.
